(19) United States
(12) Patent Application Publication
(10) Pub. No.: US 2026/0090250 A1
(43) Pub. Date: Mar. 26, 2026

(54) Organic Light-Emitting Diode Display with a Transparent Conductive Oxide Cathode

(71) Applicant: Apple Inc., Cupertino, CA (US)

(72) Inventors: Yue Qu, Redwood City, CA (US); Chih-Lei Chen, Taichung (TW); Chun-Kai Chang, Zhubei (TW); Hoyeon Kim, Campbell, CA (US); KiBeom Kim, Seoul (KR); Kwang Ohk Cheon, Dublin, CA (US); Li-An Liu, Keelung (TW); Liping Zhu, Santa Clara, CA (US); Ming-Hung Huang, Hsinchu City (TW); Pei-Ling Lin, New Taipei City (TW); Rui Liu, Los Altos, CA (US); Shiyi Liu, San Jose, CA (US); Sukru Ekin Kocabas, Santa Clara, CA (US); Wendi Chang, Sunnyvale, CA (US); Xiangyu Fu, San Jose, CA (US); Yifan Zhang, Palo Alto, CA (US); Younggu Lee, San Jose, CA (US); Yun Liu, Sunnyvale, CA (US); Xiao Li, Santa Clara, CA (US); Yu Wang, Santa Clara, CA (US)

(21) Appl. No.: 19/278,007

(22) Filed: Jul. 23, 2025

Related U.S. Application Data
(60) Provisional application No. 63/697,104, filed on Sep. 20, 2024.

(51) Int. Cl. H10K 59/80; H10K 50/17; H10K 59/35

(52) U.S. Cl. CPC H10K 59/876; H10K 50/171; H10K 59/353; H10K 59/80524

(57) ABSTRACT

Pixels in an organic light-emitting diode (OLED) display may have optical cavities defined by a partially transparent cathode layer and a reflective anode structure. Light at a wavelength emitted by a pixel may form a standing wave between the anode and the cathode. The standing wave may have an upper antinode and a lower antinode. Pixels of different colors may have emissive layers aligned with different antinodes. The OLED layers for the pixels may include an electron transport layer that is doped with a low work function material. The cathode may include one or more layers of transparent conductive oxide and/or metal. The cathode may be shorted to a metal mesh and/or a conductive cutting structure to decrease resistance.

This application claims the benefit of U.S. provisional Ser. No. 63/697,104, filed Sep. 20, 2024, which is hereby incorporated by reference herein in its entirety.

### BACKGROUND

This relates generally to electronic devices, including electronic devices with displays.

Electronic devices often include displays. For example, an electronic device may have an organic light-emitting diode (OLED) display based on organic light-emitting diode pixels. In this type of display, each pixel includes a light-emitting diode and transistors for controlling application of a signal to the light-emitting diode to produce light. The light-emitting diodes may include OLED layers positioned between an anode and a cathode. To emit light from a given pixel in an organic light-emitting diode display, a voltage may be applied to the anode and the cathode of the given pixel.

It is within this context that the embodiments herein arise.

### SUMMARY

A display may include a plurality of pixels. Each pixel in the plurality of pixels may include an anode, a cathode, and organic light-emitting diode layers that are interposed between the anode and the cathode. The organic light-emitting diode layers may include an emissive layer, light at a wavelength emitted by the pixel may form a standing wave between the anode and the cathode, the standing wave may have first and second antinodes, the first antinode may be interposed between the cathode and the second antinode, the emissive layer may be aligned with the first antinode for pixels of a first color in the plurality of pixels, and the emissive layer is aligned with the second antinode for pixels of a second color that is different than the first color in the plurality of pixels.

A display may include a plurality of pixels. Each pixel in the plurality of pixels may include an anode, a cathode comprising a transparent conductive oxide layer, and organic light-emitting diode layers that are interposed between the anode and the cathode. The organic light-emitting diode layers may include an emissive layer, an electron injection layer that is interposed between the emissive layer and the cathode, and an electron transport layer that is interposed between the emissive layer and the electron injection layer. The electron injection layer may include a first material having a first work function that is less than 5 eV, the electron transport layer may include a bulk material and a dopant, and the dopant may include a second material having a second work function that is less than 5 eV.

A display may include a plurality of pixels. Each pixel in the plurality of pixels may include an anode and organic light-emitting diode layers that overlap the anode. The organic light-emitting diode layers may include an emissive layer, a hole transport layer interposed between the emissive layer and the anode, a hole injection layer interposed between the hole transport layer and the anode, an electron transport layer, and an electron injection layer. The emissive layer may be interposed between the electron transport layer and the hole transport layer, the electron transport layer may be interposed between the electron injection layer and the emissive layer, and the electron injection layer may serve as a cathode for the pixel. Each pixel in the plurality of pixels may include one or more dielectric layers that overlap the organic light-emitting diode layers. The one or more dielectric layers may be in direct contact with an upper surface of the electron injection layer.

### BRIEF DESCRIPTION OF THE DRAWINGS

FIG. 1 is a schematic diagram of an illustrative electronic device having a display in accordance with some embodiments.

FIG. 2 is a schematic diagram of an illustrative display in accordance with some embodiments.

FIG. 3 is a diagram of an illustrative display pixel circuit in accordance with some embodiments.

FIG. 4 is a cross-sectional side view of an illustrative display with organic light-emitting diode pixels and a cathode comprising transparent conductive oxide in accordance with some embodiments.

FIG. 5 is a cross-sectional side view of an illustrative pixel with organic light-emitting diode layers comprising a doped electron transport layer in accordance with some embodiments.

FIG. 6 is a cross-sectional side view of an illustrative pixel with organic light-emitting diode layers comprising an electron injection layer that serves as a cathode in accordance with some embodiments.

FIG. 7A is a cross-sectional side view of an illustrative cathode with three conductive layers in accordance with some embodiments.

FIG. 7B is a cross-sectional side view of an illustrative cathode with two conductive layers in accordance with some embodiments.

FIG. 8 is a schematic diagram of an illustrative display with organic light-emitting diode pixels having standing waves aligned with emissive layers in accordance with some embodiments.

FIG. 9A is a cross-sectional side view of an illustrative display with a metal mesh on an upper surface of a cathode in accordance with some embodiments.

FIG. 9B is a top view of the illustrative display of FIG. 9A in accordance with some embodiments.

FIG. 10 is a cross-sectional side view of an illustrative display with a conductive cutting structure in accordance with some embodiments.

FIG. 11 is a cross-sectional side view of an illustrative display with organic light-emitting diode pixels, a cathode comprising transparent conductive oxide, and a circular polarizer in accordance with some embodiments.

### DETAILED DESCRIPTION

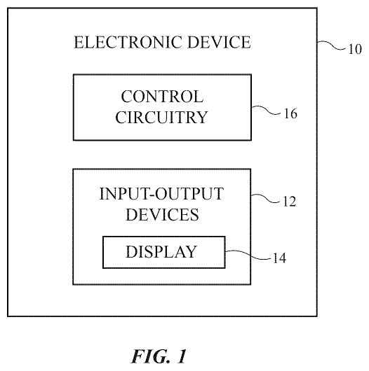

An illustrative electronic device of the type that may be provided with a display is shown in FIG. 1. Electronic device 10 may be a computing device such as a laptop computer, a computer monitor containing an embedded computer, a tablet computer, a cellular telephone, a media player, or other handheld or portable electronic device, a smaller device such as a wrist-watch device, a pendant device, a headphone or earpiece device, a device embedded in eyeglasses or other equipment worn on a user's head, or other wearable or miniature device, a display, a computer display that contains an embedded computer, a computer display that does not contain an embedded computer, a gaming device, a navigation device, an embedded system such as a system in which electronic equipment with a display is mounted in a kiosk or automobile, or other electronic equipment. Electronic device 10 may have the shape of a pair of eyeglasses (e.g., supporting frames), may form a housing having a helmet shape, or may have other configurations to help in mounting and securing the components of one or more displays on the head or near the eye of a user.

As shown in FIG. 1, electronic device 10 may include control circuitry 16 for supporting the operation of device 10. Control circuitry 16 may include storage such as hard disk drive storage, nonvolatile memory (e.g., flash memory or other electrically-programmable-read-only memory configured to form a solid state drive), volatile memory (e.g., static or dynamic random-access memory), etc. Processing circuitry in control circuitry 16 may be used to control the operation of device 10. The processing circuitry may be based on one or more microprocessors, microcontrollers, digital signal processors, baseband processors, power management units, audio chips, application-specific integrated circuits, etc.

Input-output circuitry in device 10 such as input-output devices 12 may be used to allow data to be supplied to device 10 and to allow data to be provided from device 10 to external devices. Input-output devices 12 may include buttons, joysticks, scrolling wheels, touch pads, key pads, keyboards, microphones, speakers, tone generators, vibrators, cameras, sensors, light-emitting diodes and other status indicators, data ports, etc. A user can control the operation of device 10 by supplying commands through input resources of input-output devices 12 and may receive status information and other output from device 10 using the output resources of input-output devices 12.

Input-output devices 12 may include one or more displays such as display 14. Display 14 may be a touch screen display that includes a touch sensor for gathering touch input from a user or display 14 may be insensitive to touch. A touch sensor for display 14 may be based on an array of capacitive touch sensor electrodes, acoustic touch sensor structures, resistive touch components, force-based touch sensor structures, a light-based touch sensor, or other suitable touch sensor arrangements. A touch sensor for display 14 may be formed from electrodes formed on a common display substrate with the display pixels of display 14 or may be formed from a separate touch sensor panel that overlaps the pixels of display 14. If desired, display 14 may be insensitive to touch (i.e., the touch sensor may be omitted). Display 14 in electronic device 10 may be a head-up display that can be viewed without requiring users to look away from a typical viewpoint or may be a head-mounted display that is incorporated into a device that is worn on a user's head. If desired, display 14 may also be a holographic display used to display holograms.

Control circuitry 16 may be used to run software on device 10 such as operating system code and applications. During operation of device 10, the software running on control circuitry 16 may display images on display 14.

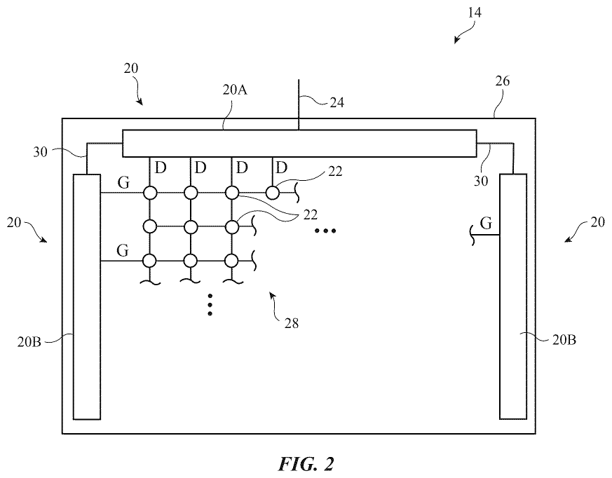

FIG. 2 is a diagram of an illustrative display 14. As shown in FIG. 2, display 14 may include layers such as substrate layer 26. Substrate layers such as layer 26 may be formed from rectangular planar layers of material or layers of material with other shapes (e.g., circular shapes or other shapes with one or more curved and/or straight edges). The substrate layers of display 14 may include glass layers, polymer layers, silicon layers, composite films that include polymer and inorganic materials, metallic foils, etc.

Display 14 may have an array of pixels 22 for displaying images for a user such as pixel array 28. Pixels 22 in array 28 may be arranged in rows and columns. The edges of array 28 may be straight or curved (i.e., each row of pixels 22 and/or each column of pixels 22 in array 28 may have the same length or may have a different length). There may be any suitable number of rows and columns in array 28 (e.g., ten or more, one hundred or more, or one thousand or more, etc.). Display 14 may include pixels 22 of different colors. As an example, display 14 may include red pixels, green pixels, and blue pixels. Pixels of other colors such as cyan, magenta, and yellow might also be used.

Display driver circuitry 20 may be used to control the operation of pixels 28. Display driver circuitry 20 may be formed from integrated circuits, thin-film transistor circuits, and/or other suitable circuitry. Illustrative display driver circuitry 20 of FIG. 2 includes display driver circuitry 20A and additional display driver circuitry such as gate driver circuitry 20B. Gate driver circuitry 20B may be formed along one or more edges of display 14. For example, gate driver circuitry 20B may be arranged along the left and right sides of display 14 as shown in FIG. 2.

As shown in FIG. 2, display driver circuitry 20A (e.g., one or more display driver integrated circuits, thin-film transistor circuitry, etc.) may contain communications circuitry for communicating with system control circuitry over signal path 24. Path 24 may be formed from traces on a flexible printed circuit or other cable. The control circuitry may be located on one or more printed circuits in electronic device 10. During operation, control circuitry (e.g., control circuitry 16 of FIG. 1) may supply circuitry such as a display driver integrated circuit in circuitry 20 with image data for images to be displayed on display 14. Display driver circuitry 20A of FIG. 2 is located at the top of display 14. This is merely illustrative. Display driver circuitry 20A may be located at both the top and bottom of display 14 or in other portions of device 10.

To display the images on pixels 22, display driver circuitry 20A may supply corresponding image data to data lines D while issuing control signals to supporting display driver circuitry such as gate driver circuitry 20B over signal paths 30. With the illustrative arrangement of FIG. 2, data lines D run vertically through display 14 and are associated with respective columns of pixels 22.

Gate driver circuitry 20B (sometimes referred to as gate line driver circuitry or horizontal control signal circuitry) may be implemented using one or more integrated circuits and/or may be implemented using thin-film transistor circuitry on substrate 26. Horizontal control lines G (sometimes referred to as gate lines, scan lines, emission control lines, etc.) run horizontally across display 14. Each gate line G is associated with a respective row of pixels 22. If desired, there may be multiple horizontal control lines such as gate lines G associated with each row of pixels. Individually controlled and/or global signal paths in display 14 may also be used to distribute other signals (e.g., power supply signals, etc.).

Gate driver circuitry 20B may assert control signals on the gate lines G in display 14. For example, gate driver circuitry 20B may receive clock signals and other control signals from circuitry 20A on paths 30 and may, in response to the received signals, assert a gate line signal on gate lines G in sequence, starting with the gate line signal G in the first row of pixels 22 in array 28. As each gate line is asserted, data from data lines D may be loaded into a corresponding row of pixels. In this way, control circuitry such as display driver circuitry 20A and 20B may provide pixels 22 with signals that direct pixels 22 to display a desired image on display 14. Each pixel 22 may have a light-emitting diode and circuitry (e.g., circuitry on substrate 26) that responds to the control and data signals from display driver circuitry 20.

Gate driver circuitry 20B may include blocks of gate driver circuitry such as gate driver row blocks. Each gate driver row block may include circuitry such output buffers and other output driver circuitry, register circuits (e.g., registers that can be chained together to form a shift register), and signal lines, power lines, and other interconnects. Each gate driver row block may supply one or more gate signals to one or more respective gate lines in a corresponding row of the pixels of the array of pixels in the active area of display 14.

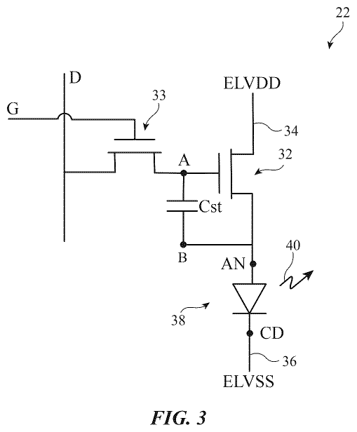

A schematic diagram of an illustrative pixel circuit of the type that may be used for each pixel 22 in array 28 is shown in FIG. 3. As shown in FIG. 3, display pixel 22 may include light-emitting diode 38. A positive power supply voltage ELVDD may be supplied to positive power supply terminal 34 and a ground power supply voltage ELVSS may be supplied to ground power supply terminal 36. Diode 38 has an anode (terminal AN) and a cathode (terminal CD). The state of drive transistor 32 controls the amount of current flowing through diode 38 and therefore the amount of emitted light 40 from display pixel 22. Cathode CD of diode 38 is coupled to ground terminal 36, so cathode terminal CD of diode 38 may sometimes be referred to as the ground terminal for diode 38.

To ensure that transistor 32 is held in a desired state between successive frames of data, display pixel 22 may include a storage capacitor such as storage capacitor Cst. The voltage on storage capacitor Cst is applied to the gate of transistor 32 at node A to control transistor 32. Data can be loaded into storage capacitor Cst using one or more switching transistors such as switching transistor 33. When switching transistor 33 is off, data line D is isolated from storage capacitor Cst and the gate voltage on terminal A is equal to the data value stored in storage capacitor Cst (i.e., the data value from the previous frame of display data being displayed on display 14). When gate line G (sometimes referred to as a scan line) in the row associated with display pixel 22 is asserted, switching transistor 33 will be turned on and a new data signal on data line D will be loaded into storage capacitor Cst. The new signal on capacitor Cst is applied to the gate of transistor 32 at node A, thereby adjusting the state of transistor 32 and adjusting the corresponding amount of light 40 that is emitted by light-emitting diode 38. If desired, the circuitry for controlling the operation of light-emitting diodes for display pixels in display 14 (e.g., transistors, capacitors, etc. in display pixel circuits such as the display pixel circuit of FIG. 3) may be formed using other configurations (e.g., configurations that include circuitry for compensating for threshold voltage variations in drive transistor 32, etc.). The display pixel may include additional switching transistors, emission transistors in series with the drive transistor, etc. Capacitor Cst may be positioned at other desired locations within the pixel (e.g., between the source and gate of the drive transistor). The display pixel circuit of FIG. 3 is merely illustrative.

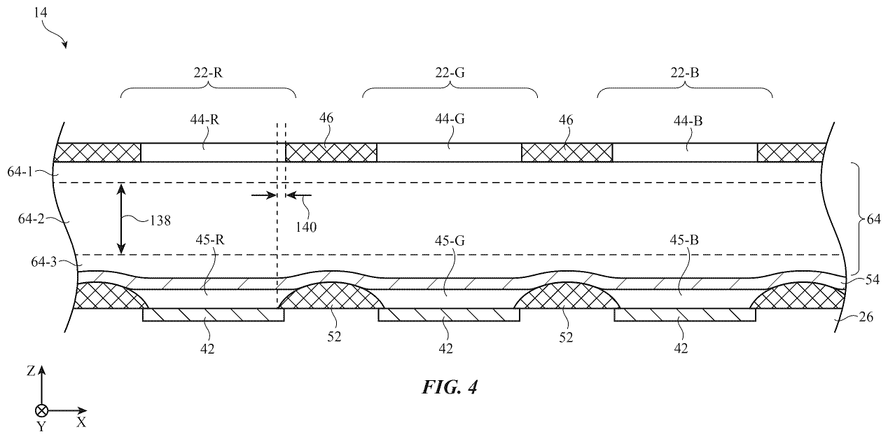

FIG. 4 is a cross-sectional side view of an illustrative display with organic light-emitting diode display pixels. As shown, display 14 may include a substrate 26. Substrate 26 may be formed from glass, plastic, polymer, silicon, or any other desired material. Substrate 26 may include transistor circuitry for applying control signals to the pixels. The transistor circuitry may include bulk transistors (where transistors are formed on the surface of a semiconductor substrate such as a silicon substrate). Another option is for the transistor circuitry to include thin-film transistors (TFTs), where a thin semiconductor film layer (e.g., formed from poly-crystalline or amorphous silicon) is formed on an insulating substrate (e.g., a glass or plastic substrate). In general, the OLED pixels described herein may include any desired combination of thin-film transistors and bulk transistors. FIG. 4 shows a red pixel 22-R, a blue pixel 22-B, and a green pixel 22-G.

Anodes 42 may be formed on substrate 26. Anodes 42 may be formed from conductive material and may be covered by OLED layers 45 and cathode 54. OLED layers 45 may include one or more layers for forming an organic light-emitting diode. For example, layers 45 may include one or more of a hole injection layer (HIL), a hole transport layer (HTL), a hole blocking layer (HBL) an electron block layer (EBL), an emissive layer (EML), an electron transport layer (ETL), an electronic injection layer (EIL), and a charge generation layer (CGL). OLED layers 45 may form a plurality of single diodes or a plurality of tandem diodes. OLED layers 45 may be formed from white OLED layers (e.g., OLED layers configured to emit white light), combinations of red, green, blue, and/or yellow OLED layers, etc. In the example of FIG. 4, red pixel 22-R includes OLED layers 45-R with a red emissive layer, green pixel 22-G includes OLED layers 45-G with a green emissive layer, and blue pixel 22-B includes OLED layers 45-B with a blue emissive layer. Display 14 may include pixel definition layer 52. The pixel definition layer defines a light-emitting aperture for each pixel in the display.

Cathode 54 may be a conductive layer formed on the OLED layers 45 and/or pixel definition layer 52. Cathode layer 54 may form a common cathode terminal (see, e.g., cathode terminal CD of FIG. 3) for all diodes in display 14. Each anode in display 14 may be independently controlled, so that each diode in display 14 can be independently controlled. This allows each pixel 22 to produce an independently controlled amount of light.

Cathode layer 54 may be formed from any desired conductive material or combination of conductive materials. Cathode 54 may be formed from a transparent or partially transparent material. Cathode 54 may be formed from a transparent conductive oxide (e.g., indium tin oxide (ITO), indium zinc oxide (IZO), aluminum zinc oxide (AZO), fluoride tin oxide (FTO), etc.). Instead or in addition, cathode 54 may comprise metal (e.g., magnesium and/or silver).

The display of FIG. 4 may use a weak optical cavity to enhance efficiency and color purity in the display. An optical cavity may be formed by reflective layers within the display that are formed on either side of the OLED layers. To form an optical cavity of this type, anodes 42 may be reflective and cathode 54 may be at least partially reflective. Increased reflectance in cathode 54 may increase the optical cavity effect in the pixels. The pixels herein may have a weak optical cavity effect (e.g., with a cathode having a transparency of greater than 80%) to improve display efficiency and luminance uniformity over a wide range of viewing angles.

Anodes 42 may reflect more than 50% of incident visible light, may reflect more than 60% of incident visible light, may reflect more than 70% of incident visible light, may reflect more than 80% of incident visible light, may reflect more than 90% of incident visible light, etc. Cathode 54 may transmit more than 50% of incident visible light, may transmit more than 60% of incident visible light, may transmit more than 70% of incident visible light, may transmit more than 80% of incident visible light, may transmit more than 90% of incident visible light, may transmit less than 95% of incident visible light, may transmit less than 90% of incident visible light, may transmit less than 85% of incident visible light, etc. Cathode 54 may reflect more than 5% of incident visible light, may reflect more than 10% of incident visible light, may reflect more than 15% of incident visible light, may reflect more than 20% of incident visible light, etc.

As shown in FIG. 4, display 14 also includes color filter elements 44 that are formed within openings in a grid of black matrix 46 (sometimes referred to as black masking layer 46, opaque masking layer 46, etc.). Each color filter element 44 may overlap a respective pixel 22 that emits light at a given color (wavelength). Each color filter element 44 may transmit light at the given wavelength for its overlapped pixel while blocking light for other wavelengths. For example, each red OLED pixel 22-R is overlapped by a red color filter 44-R that transmits red light while blocking blue light and green light. Each green OLED pixel 22-G is overlapped by a green color filter 44-G that transmits green light while blocking blue light and red light. Each blue OLED subpixel 22-B is overlapped by a blue color filter 44-B that transmits blue light while blocking red light and green light.

The color filter elements 44 allow light from the display pixels to pass through to the viewer. Therefore, the display performance is not negatively impacted by the color filter elements. Simultaneously, the color filter elements 44 block much of the ambient light from being reflected. Each blue color filter element blocks red and green ambient light from being reflected, each red color filter element blocks blue and green ambient light from being reflected, and each green color filter element blocks red and blue ambient light from being reflected. Each color filter element may therefore block approximately ⅔ of incident ambient light.

Black matrix 46 may be formed from any desired material that absorbs light. Black matrix 46 may reflect less than 20% of incident light, less than 10% of incident light, less than 5% of incident light, less than 3% of incident light, less than 1% of incident light, etc. Black matrix 46 may transmit less than 20% of incident light, less than 10% of incident light, less than 5% of incident light, less than 3% of incident light, less than 1% of incident light, etc. Black matrix 46 may absorb more than 50% of incident light, more than 75% of incident light, more than 90% of incident light, more than 95% of incident light, etc. Black matrix 46 blocks ambient light from reflecting off the display.

In FIG. 4, one or more planarization and/or passivation layers 64 may be formed between cathode 54 and color filter elements 44 and black matrix 46. The one or more planarization layers 64 has first and second opposing sides. Cathode 54 (and the OLED pixels 22) is formed on the first (lower) side whereas color filter elements 44 and black matrix 46 are formed on the second (upper) side. The one or more planarization and/or passivation layers 64 may include an organic dielectric layer 64-2 that is deposited using inkjet printing (IJP). The organic dielectric layer may sometimes be referred to as an organic planarization layer 64-2 or simply planarization layer 64-2. The organic dielectric material may be interposed between first and second inorganic passivation layers 64-1 and 64-3. The planarization and/or passivation layers 64 may sometime be referred to as dielectric layer(s) 64. Color filter elements 44 and black matrix 46 may be formed in direct contact with an upper surface of dielectric layer(s) 64. Cathode 54 may be formed in direct contact with a lower surface of dielectric layer(s) 64.

To improve luminance uniformity across a wide range of viewing angles, the thickness 138 of planarization layer 64-2 may be relatively low. Thickness 138 may be less than 6 microns, less than 4 microns, less than 3 microns, between 1 micron and 3 microns, etc.

To improve luminance uniformity across a wide range of viewing angles, there may be an offset 140 along the X-axis between the edge of the light-emitting aperture for a given pixel and the edge of the black matrix for the given pixel. The magnitude of offset 140 may be greater than 2 microns, greater than 4 microns, greater than 6 microns, greater than 8 microns, greater than 10 microns, between 3 microns and 7 microns, between 3 microns and 20 microns, between 7 microns and 15 microns, etc.

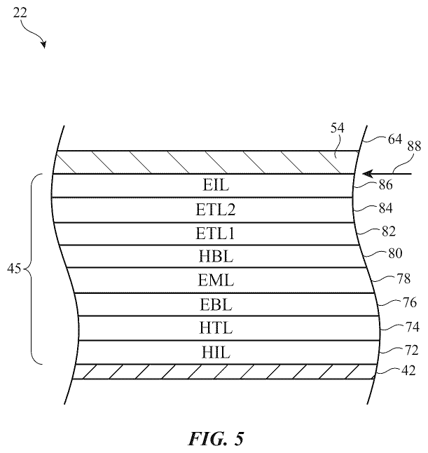

FIG. 5 is a cross-sectional side view of an illustrative pixel with OLED layers 45 interposed between a respective anode 42 and cathode 54. As shown in FIG. 5, OLED layers 45 may include hole injection layer (HIL) 72 formed on anode 42, hole transport layer (HTL) 74 formed on HIL 72, electronic blocking layer (EBL) 76 formed on HTL 74, emissive layer (EML) 78 formed on EBL 76, hole blocking layer (HBL) 80 formed on EML 78, electron transport layer (ETL1) 82 formed on HBL 80, doped electronic transport layer (ETL2) 84 formed on ETL1 82, and electron injection layer (EIL) 86 formed on ETL2 84.

In red pixels, the emissive layer may be a red emissive layer. In green pixels, the emissive layer may be a green emissive layer. In blue pixels, the emissive layer may be a blue emissive layer.

Electron injection layer 86 may include a low work function material (e.g., metal) such as lithium, sodium, potassium, cesium, magnesium, calcium, barium, and/or ytterbium. The low work function material may have a work function that is less than 5 eV, less than 4 eV, less than 3 eV, etc.

Electron transport layers(s) 82 and 84 may support the transport of electrons to reach the emissive layer. Each one of electron transport layer(s) 82 and 84 may have a bulk material (e.g., the ETL material) such as a metal chelate (e.g., Tris(8-hydroxyquinolinato)aluminum), an oxadiazole compound, or another desired material. The bulk material for layers 82 and 84 may be the same or may be different. Layer 82 may have no additional dopant whereas doped layer 84 has an additional dopant. Doped electron transport layer 84 may be doped with a low work function material (e.g., metal) such as lithium, sodium, potassium, cesium, magnesium, calcium, barium, and/or ytterbium. The dopant may have a work function that is less than 5 eV, less than 4 eV, less than 3 eV, etc. The dopant in layer 84 may be the same low work function material that is used in electron injection layer 86 or may be a different low work function material than is used in electron injection layer 86. Including the low work function dopant in electronic transport layer 84 adjacent to electronic injection layer 86 may improve the efficiency of the pixels.

The thickness of doped electron transport layer 84 may be less than 10 nanometers, less than 5 nanometers, less than 3 nanometers, less than 1 nanometer, greater than 10 nanometers, greater than 5 nanometers, greater than 3 nanometers, greater than 1 nanometer, between 1 nanometer and 20 nanometers, etc. The doped electron transport layer 84 may comprise (by weight) between 0.01% and 10% dopant, greater than 0.01% dopant, greater than 0.1% dopant, greater than 1% dopant, greater than 5% dopant, greater than 10% dopant, less than 0.01% dopant, less than 0.1% dopant, less than 1% dopant, less than 5% dopant, less than 10% dopant, etc. The remaining weight percentage of the doped electron transport layer is the weight percentage of the bulk material in the doped electron transport layer.

In some circumstances, particles may cause a short circuit between the anode and the cathode of a given pixel. When a particle is present on an upper surface of anode 42, the deposition of the subsequent layers (e.g., OLED layers 45 and cathode 54) may undesirably result in a portion of cathode 54 being shorted to anode 42. Higher step coverage in cathode 54 may be associated with increased numbers of short circuits between cathode 54 and anode 42 caused by intervening particles whereas lower step coverage in cathode 54 may be associated with decreased numbers of short circuits between cathode 54 and anode 42 caused by intervening particles.

To mitigate short circuits between anode 42 and cathode 54, an additional layer may be included between cathode 54 and electron injection layer 86. As shown in FIG. 5, a high impedance layer may be included at position 88 between cathode 54 and electron injection layer 86. The high impedance layer may comprise niobium pentoxide, molybdenum trioxide, rhenium trioxide, tin oxide, zinc oxide, and/or another desired material. The presence of the high impedance layer may prevent direct contact between anode 42 and cathode 54 (even when a particle is present between anode 42 and cathode 54 during manufacturing).

Instead or in addition, electron injection layer 86 may be a conformal EIL to mitigate short circuits between anode 42 and cathode 54.

Instead or in addition, cathode 54 may be a collimated cathode that is deposited with reduced step coverage to mitigate short circuits between anode 42 and cathode 54.

Instead or in addition, cathode 54 may be a thermal evaporated cathode with reduced step coverage to mitigate short circuits between anode 42 and cathode 54.

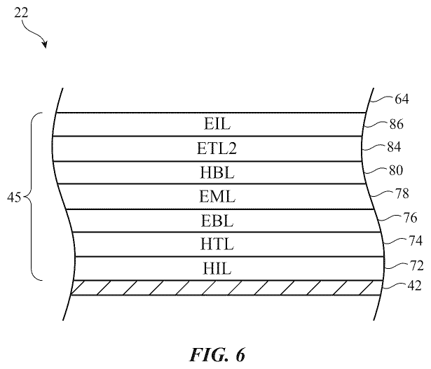

Instead or in addition, electron injection layer 86 may be used as the cathode for the pixels to mitigate short circuits between anode 42 and cathode 54. An example of this type is shown in FIG. 6. As shown in FIG. 6, dedicated cathode 54 is omitted and electron injection layer 86 instead serves as the cathode for pixel 22. With this type of arrangement, dielectric layer(s) 64 are formed in direct contact with the upper surface of electron injection layer 86 (without an intervening separate cathode layer between the upper surface of electron injection layer 86 and dielectric layer(s) 64).

The example in FIG. 5 of including electron transport layer 82 and doped electron transport layer 84 in OLED layers 45 is merely illustrative. In another possible arrangement, electron transport layer 82 may be omitted. As shown in FIG. 6, a lower surface of doped electron transport layer 84 may be in direct contact with hole blocking layer 80 and an upper surface of doped electron transport layer 84 may be in direct contact with electron injection layer 86.

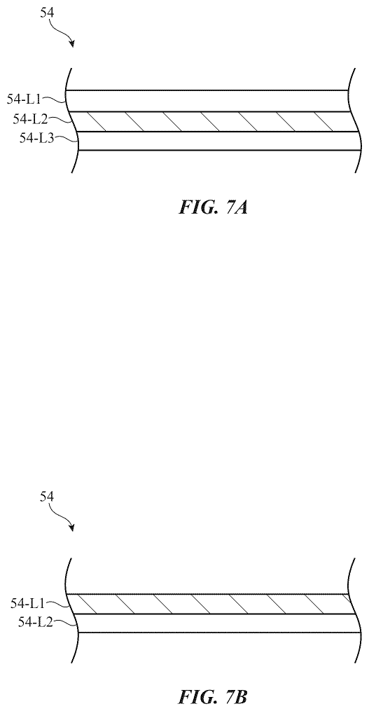

When cathode 54 comprises only a layer of transparent conductive oxide, the resistance of the cathode may be higher than desired (causing higher levels of IR drop than are desired). To mitigate the resistance of a cathode comprising transparent conductive oxide, the cathode may additionally include one or more additional conductive layers. FIG. 7A shows an example where cathode 54 includes a first conductive layer 54-L1, a second conductive layer 54-L2, and a third conductive layer 54-L3. Conductive layers 54-L1 and 54-L3 may be formed from transparent conductive oxide layers. Conductive layers 54-L1 and 54-L3 may be formed from the same material or from different materials. Conductive layer 54-L2, meanwhile, may be formed from a non-oxide metal material. Conductive layer 54-L2 may comprise silver, aluminum, magnesium, gold, or a combination of two or more metals. As specific examples, conductive layer 54-L2 may be a layer of silver, a layer of aluminum, or a layer of a magnesium silver alloy.

Including metal layer 54-L2 in cathode 54 in addition to transparent conductive oxide layers 54-L1 and 54-L3 (as in FIG. 7A) may decrease the total resistance of the cathode. The thickness of layer 54-L2 may be less than the thickness of transparent conductive oxide layers 54-L1 and 54-L3. In one example, layer 54-L1 has a thickness of 40 nanometers, layer 54-L2 has a thickness of 8 nanometers, and layer 54-L3 has a thickness of 40 nanometers. In another example, layer 54-L1 has a thickness of 40 nanometers, layer 54-L2 has a thickness of 14 nanometers, and layer 54-L3 has a thickness of 40 nanometers. In one example, layer 54-L1 has a thickness of 40 nanometers, layer 54-L2 has a thickness of 16 nanometers, and layer 54-L3 has a thickness of 40 nanometers. The thicknesses of layers 54-L1 and 54-L3 may be the same or may be different. The thickness of each one of layers 54-L1, 54-L2, and 54-L3 may be greater than 5 nanometers, greater than 10 nanometers, greater than 25 nanometers, greater than 50 nanometers, less than 100 nanometers, less than 50 nanometers, less than 25 nanometers, etc.

The example in FIG. 7A of cathode 54 including a metal layer between two transparent conductive oxide layers is merely illustrative. In another possible arrangement, shown in FIG. 7B, cathode 54 may include conductive layer 54-L1 and conductive layer 54-L2. Conductive layer 54-L1 may be formed from transparent conductive oxide. Conductive layer 54-L2, meanwhile, may be formed from a non-oxide metal material. Conductive layer 54-L2 may comprise silver, aluminum, magnesium, gold, or a combination of two or more metals. As specific examples, conductive layer 54-L2 may be a layer of silver, a layer of aluminum, or a layer of a magnesium silver alloy.

Including metal layer 54-L2 in cathode 54 in addition to transparent conductive oxide layer 54-L1 (as in FIG. 7B) may decrease the total resistance of the cathode.

In addition to decreasing the resistance of cathode 54, including a metal layer in the cathode in addition to one or more transparent conductive oxide layers (as in FIGS. 7A and 7B) may mitigate the requirements for the thickness of the one or more transparent conductive oxide layers, thereby reducing step coverage which mitigates short circuits between anode 42 and cathode 54. Including a metal layer in the cathode in addition to one or more transparent conductive oxide layers therefore mitigates short circuits between anode 42 and cathode 54.

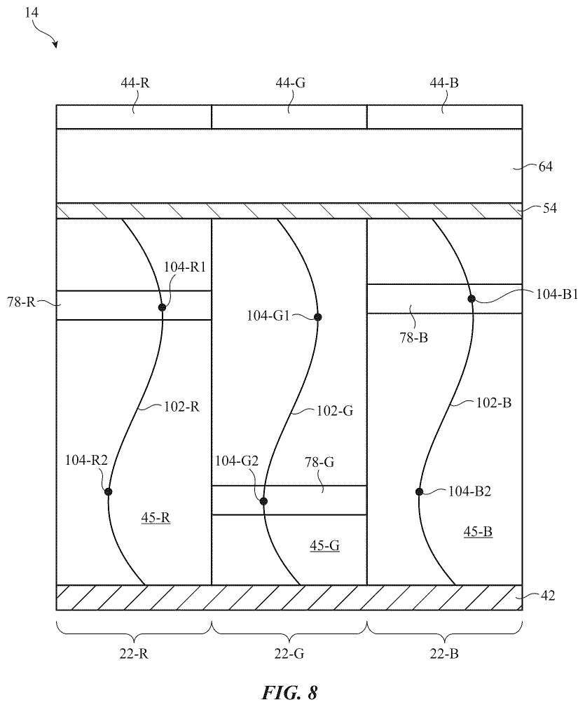

To optimize emission of the desired color of light for a given pixel, the emissive layer for the given pixel may be aligned with one of the antinodes of the standing wave for that pixel. Antinodes refer to the points on the standing wave having a maximum amplitude. Each standing wave in the OLED display of FIG. 4 has two antinodes. FIG. 8 is a schematic diagram showing the antinodes of each pixel in the display.

As shown in FIG. 8, red pixel 22-R has a standing wave 102-R with first and second antinodes 104-R1 and 104-R2. The first antinode 104-R1 is closer to cathode 54 than the second antinode 104-R2. Antinode 104-R1 may be referred to as an upper antinode and antinode 104-R2 may be referred to as a lower antinode. Green pixel 22-G has a standing wave 102-G with first and second antinodes 104-G1 and 104-G2. The first antinode 104-G1 is closer to cathode 54 than the second antinode 104-G2. Antinode 104-G1 may be referred to as an upper antinode and antinode 104-G2 may be referred to as a lower antinode. Blue pixel 22-B has a standing wave 102-B with first and second antinodes 104-B1 and 104-B2. The first antinode 104-B1 is closer to cathode 54 than the second antinode 104-B2. Antinode 104-B1 may be referred to as an upper antinode and antinode 104-B2 may be referred to as a lower antinode.

The emissive layer for a given pixel may be aligned with either one of the antinodes of the standing wave for that pixel. Aligning the emissive layer for a given pixel with the lower antinode of the standing wave for that pixel may improve luminance uniformity across a wide range of viewing angles. Aligning the emissive layer for a given pixel with the upper antinode of the standing wave for that pixel may improve efficiency.

In the example of FIG. 8, red emissive layer 78-R is aligned with upper antinode 104-R1, green emissive layer 78-G is aligned with lower antinode 104-G2, and blue emissive layer 78-B is aligned with upper antinode 104-B1. Green pixels may be the main driver of off-axis luminance uniformity performance and therefore green emissive layer 78-G is aligned with lower antinode 104-G2 to improve off-axis luminance uniformity performance. Red and blue pixels may be the main driver of display efficiency and therefore red emissive layer 78-R and blue emissive layer 78-B are aligned with respective upper antinodes to improve display efficiency. This arrangement may optimize performance of display 14.

The example of FIG. 8 with some colored pixels having emissive layers aligned with an upper antinode and some, different colored pixels having emissive layers aligned with a lower antinode is merely illustrative. In another possible arrangement, the red, blue, and green pixels may all have emissive layers aligned with a respective upper antinode. In yet another possible arrangement, the red, blue, and green pixels may all have emissive layers aligned with a respective lower antinode.

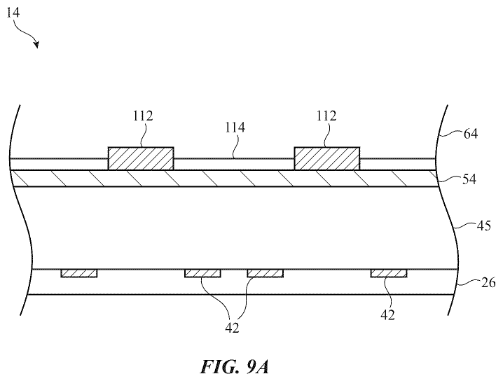

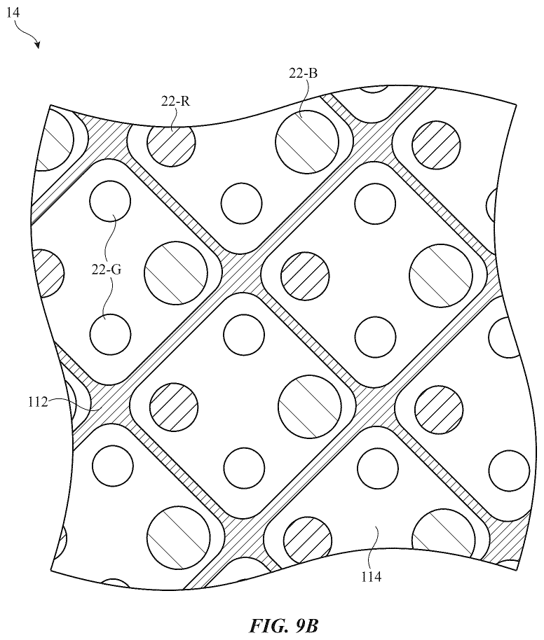

To further mitigate resistance of the cathode, a metal mesh may be formed in direct contact with a transparent conductive oxide layer in the cathode. FIG. 9A is a cross-sectional side view of a display with a metal mesh layer that is shorted to a transparent conductive oxide layer. As shown in FIG. 9A, cathode 54 is formed on an upper surface of OLED layers 45 (similar to as shown in FIG. 4). Cathode 54 may be formed from a transparent conductive oxide material. Metal mesh layer 112 is formed on an upper surface of cathode 54. The metal mesh layer 112 may overlap gaps between adjacent pixels and therefore may be opaque (without mitigating display efficiency). Metal mesh 112 may be less transparent than cathode 54. The presence of metal mesh layer 112 shorted to cathode 54 advantageously mitigates the resistance of cathode 54 (mitigating IR drop across the display).

During manufacturing of metal mesh 112, a fine metal mask (FMM) may be used to deposit an organic masking layer 114 on the upper surface of cathode 54. The organic masking layer 114 may be included on all portions of the cathode that metal mesh 112 is not intended to overlap. After the organic masking layer 114 is deposited, metal mesh 112 may be formed in the gaps of organic masking layer 114 in direct contact with cathode 54. Organic masking layer 114 overlaps light-emitting areas of the pixels and may have a transparency of greater than 80%, greater than 90%, greater than 95%, greater than 98%, etc.

FIG. 9B is a top view of the illustrative display of FIG. 9A with metal mesh 112 and organic masking layer 114. As shown in FIG. 9B, display 14 includes red pixels 22-R, green pixels 22-G, and blue pixels 22-B. Metal mesh 112 may have a mesh footprint that defines a plurality of openings. In FIG. 9B, each opening in the metal mesh overlaps two green pixels, one red pixel, and one blue pixel. This example is merely illustrative. In general, the size of the openings in the metal mesh may be selected to optimize cathode resistance, manufacturing cost, manufacturing complexity, etc. Each opening in the metal mesh may overlap only one pixel (e.g., one green pixel, one red pixel, or one blue pixel), two pixels, three pixels, four pixels (as in FIG. 9B), more than four pixels, more than ten pixels, more than twenty pixels, etc.

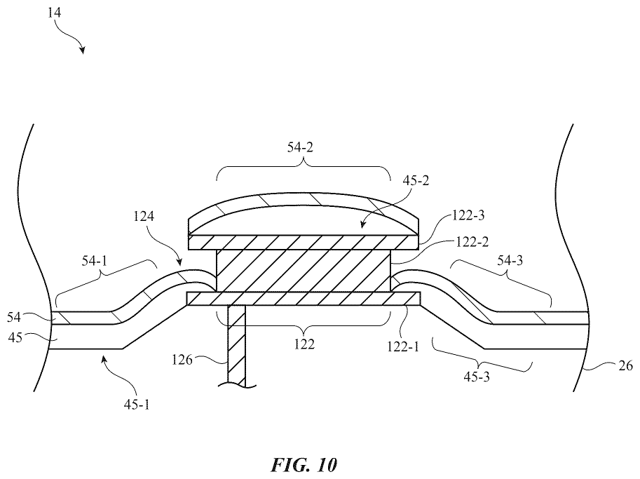

The example in FIGS. 9A and 9B of decreasing cathode resistance using a metal mesh on an upper surface of the cathode is merely illustrative. In another possible arrangement, shown in FIG. 10, a conductive cutting structure may be shorted to cathode 54 to decrease cathode resistance. FIG. 10 is a cross-sectional side view of an illustrative display with a conductive cutting structure. Conductive cutting structure 122 may be formed on an upper surface of substrate 26 between adjacent pixels. Light-emitting pixels may be formed on either side of the conductive cutting structure. The conductive cutting structure may have the same footprint as the footprint for metal mesh 112 shown in FIG. 9B. In other words, the conductive cutting structure may optionally have a mesh layout.

The conductive cutting structure 122 may include multiple layers such as conductive layer 122-1, conductive layer 122-2, and conductive layer 122-3. The multiple conductive layers may define undercuts such as undercut 124 on both sides of the conductive cutting structure. Each conductive layer in conductive cutting structure 122 may be formed from aluminum, molybdenum, titanium, or any other desired conductive material.

Conductive cutting structure 122 may be formed on substrate 26 before deposition of OLED layers 45 and cathode 54. When OLED layers 45 and cathode 54 are deposited over the conductive cutting structure, the conductive cutting structure may divide the OLED layers 45 and cathode 54 into three discrete portions. As shown in FIG. 10, OLED layers 45 have a first discrete portion 45-1 on a first side of the conductive cutting structure, a second discrete portion 45-2 on an upper surface of the conductive cutting structure, and a third discrete portion 45-3 on a second side of the conductive cutting structure. Similarly, cathode 54 have a first discrete portion 54-1 on the first side of the conductive cutting structure, a second discrete portion 54-2 on the upper surface of the conductive cutting structure, and a third discrete portion 54-3 on the second side of the conductive cutting structure.

Cutting the OLED layers into multiple discrete portions may mitigate lateral leakage of display current through the OLED layers (which may otherwise cause unintended luminance in one or more pixels). Additionally, cathode 54 may contact conductive cutting structure 122 within undercut 124 (e.g., the cathode may contact a side surface of conductive layer 122-2 as shown in FIG. 10). Conductive cutting structure 122 therefore maintains continuity of the cathode by electrically connecting discrete cathode portions 54-1 and 54-3. Moreover, conductive cutting structure 122 may mitigate the resistance of the cathode. Conductive cutting structure 122 may also be connected to a power supply voltage (ELVSS) in the active area of the display (e.g., using a via in substrate 26 such as via 126). This direct connection to ELVSS at one or more points across display 14 may ensure a uniform ELVSS across display 14.

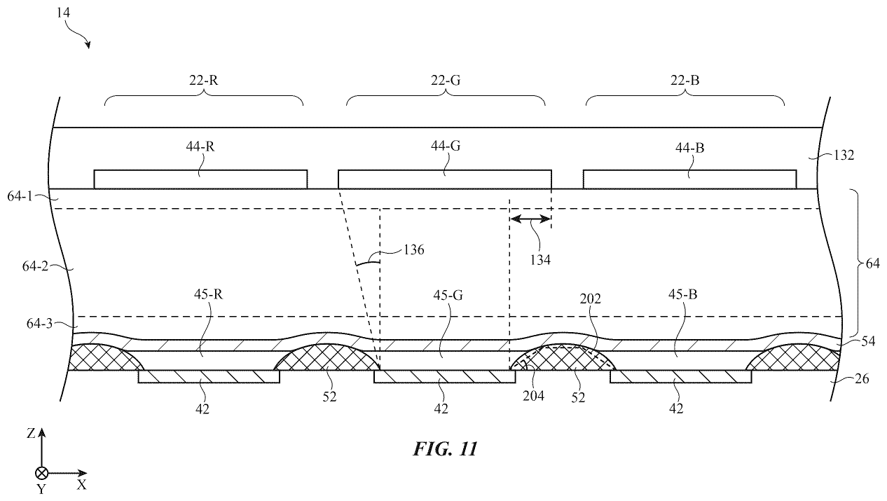

Some displays may include a circular polarizer to mitigate reflections of ambient light. FIG. 11 is a cross-sectional side view of an illustrative display with a circular polarizer. Display 14 in FIG. 11 is similar to display 14 in FIG. 4 and descriptions of duplicate components will not be repeated for simplicity. In FIG. 4, planarization and/or passivation layers 64 are overlapped by color filter elements 44 and black matrix 46. No circular polarizer is included over pixels 22 in display 14 in FIG. 4. This type of display may sometimes be referred to as a polarizer-free display, a circular-polarizer-free display, a polarizer-free OLED display, circular-polarizer-free OLED display etc. In contrast with the polarizer-free display of FIG. 4, display 14 of FIG. 11 includes circular polarizer 132.

Circular polarizer 132 in FIG. 11 may include a linear polarizer and a quarter wave plate. The circular polarizer serves to mitigate undesired reflections of ambient light off of display 14. When ambient light passes in the negative Z-direction through circular polarizer 132, the light becomes circularly polarized. The light may subsequently reflect off of reflective layers of display panel 14 (e.g., reflective anodes 42). The reflected light (now traveling in the positive Z-direction) has the opposite circular polarization and is subsequently absorbed by the circular polarizer 132. The circular polarizer 132 therefore effectively prevents ambient light reflections off of display 14, improving contrast in display 14.

When circular polarizer 132 is included in display 14 (as in FIG. 11), black matrix 46 may be omitted. However, each color filter element 44 may be larger than a corresponding light-emitting aperture in pixel definition layer 52 associated with that pixel. Consequently, there is an offset distance 134 along the X-axis between the edge of the light-emitting aperture and the edge of the color filter element. The offset distance 134 may be present around the entire periphery of the light-emitting aperture. Having each color filter element 44 be larger than a corresponding light-emitting aperture in pixel definition layer 52 may ensure that all of the emitted light from a given pixel passes through the color filter element for that pixel.

A ray between the edge of the light-emitting aperture for a given pixel and the edge of the color filter element for that given pixel may be characterized by an angle 136 relative to the surface normal of the display. Offset distance 134 may be sufficiently large to cause the magnitude of angle 136 to be greater than a critical reflection angle associated with an air-glass interface. Angle 136 may be between 40 degrees and 45 degrees, between 40 and 50 degrees, between 35 degrees and 55 degrees, etc. The magnitude of offset distance 134 may be greater than 2 microns, greater than 4 microns, greater than 6 microns, greater than 8 microns, greater than 10 microns, between 3 microns and 7 microns, between 3 microns and 20 microns, between 7 microns and 15 microns, etc.

When color filter elements and a circular polarizer are included in the display as in FIG. 11, each pixel may have a relatively broad photoluminescence spectra. The color filtering provided by the color filter may narrow the spectra of the light ultimately emitted by the pixel after the light passes through the color filter.

In another possible arrangement, color filter elements 44 may be omitted from display 14 in FIG. 11. In this example, each pixel may have a relatively narrow photoluminescence spectra. As one example, green pixel 22-G may have a spectra with a peak at 522 nanometers and a full width at half maximum (FWHM) of less than 30 nanometers. FWHM refers to the full width of the photoluminescence profile at half of the maximum intensity. In general, the FWHM of the red, blue, and/or green pixels may be less than 75 nanometers, less than 65 nanometers, less than 60 nanometers, less than 55 nanometers, less than 50 nanometers, less than 45 nanometers, less than 40 nanometers, greater than 45 nanometers, greater than 40 nanometers, greater than 25 nanometers, between 25 nanometers and 50 nanometers, between 25 nanometers and 60 nanometers, between 30 nanometers and 50 nanometers, between 35 nanometers and 50 nanometers, between 40 nanometers and 50 nanometers, etc.

Pixel definition layer 52 may optionally have a low optical density. Optical density has the units μm⁻¹, where the transmission percentage is determined by the formula 1/(10^{OD}). The OD of pixel definition layer 52 in FIG. 11 may be greater than 1.0 μm⁻¹, greater than 1.3 μm⁻¹, less than 1.0 μm⁻¹, less than 0.8 μm⁻¹, less than 0.6 μm⁻¹, between 0.5 μm⁻¹ and 1.0 μm⁻¹, etc.

The thickness of pixel definition layer 52 may gradually decrease from a maximum thickness to a thickness of 0 at a point that overlaps anode 42. The thickness of the pixel definition layer therefore decreases with decreasing separation from a center of a respective subpixel. Pixel definition layer 52 may have an upper surface with curved surfaces (as in FIG. 11) or may have one or more tapered surfaces (as shown by optional cross-sectional profile 202 in FIG. 11). These types of arrangements may help achieve a smooth reflectance transition which desirable mitigates diffractive artifacts. The tapered surfaces of cross-sectional profile 202 may be characterized by a taper angle 204. Taper angle 204 may be between 15 degrees and 45 degrees, between 10 degrees and 50 degrees, between 20 degrees and 40 degrees, between 25 degrees and 35 degrees, between 35 degrees and 45 degrees, between 15 degrees and 25 degrees, etc.

The foregoing is merely illustrative and various modifications can be made by those skilled in the art without departing from the scope and spirit of the described embodiments. The foregoing embodiments may be implemented individually or in any combination.

What is claimed is:

1. A display comprising a plurality of pixels, wherein each pixel in the plurality of pixels comprises:
an anode;
a cathode; and
organic light-emitting diode layers that are interposed between the anode and the cathode, wherein the organic light-emitting diode layers include an emissive layer, wherein light at a wavelength emitted by the pixel forms a standing wave between the anode and the cathode, wherein the standing wave has first and second antinodes, wherein the first antinode is interposed between the cathode and the second antinode, wherein, for pixels of a first color in the plurality of pixels, the emissive layer is aligned with the first antinode, and wherein, for pixels of a second color that is different than the first color in the plurality of pixels, the emissive layer is aligned with the second antinode.

2. The display defined in claim 1, wherein, for pixels of a third color that is different than the first and second colors in the plurality of pixels, the emissive layer is aligned with the first antinode.

3. The display defined in claim 2, wherein the first color is red, the second color is green, and the third color is blue.

4. The display defined in claim 1, wherein the second color is green.

5. The display defined in claim 1, wherein the organic light-emitting diode layers for each pixel in the plurality of pixels further comprise:
an electron injection layer that is interposed between the emissive layer and the cathode, wherein the electron injection layer comprises a first material having a first work function that is less than 4 eV; and
an electron transport layer that is interposed between the emissive layer and the electron injection layer, wherein the electron transport layer comprises a bulk material and a dopant and wherein the dopant comprises a second material having a second work function that is less than 4 eV.

6. The display defined in claim 5, wherein the second material is the same as the first material.

7. The display defined in claim 5, wherein the first material comprises a material selected from the group consisting of: lithium, sodium, potassium, cesium, magnesium, calcium, barium, and ytterbium.

8. The display defined in claim 5, wherein the second material comprises a material selected from the group consisting of: lithium, sodium, potassium, cesium, magnesium, calcium, barium, and ytterbium.

9. The display defined in claim 5, wherein the dopant comprises between 0.01% and 10% of the electron transport layer by weight.

10. The display defined in claim 5, wherein the organic light-emitting diode layers for each pixel in the plurality of pixels further comprise:
an additional electron transport layer that is interposed between the emissive layer and the electron transport layer.

11. The display defined in claim 1, wherein the cathode comprises:
a first transparent conductive oxide layer; and
a metal layer.

12. The display defined in claim 11, wherein the cathode comprises:
a second transparent conductive oxide layer, wherein the metal layer is interposed between the first and second transparent conductive oxide layers.

13. The display defined in claim 1, further comprising:
a metal mesh that is formed on an upper surface of the cathode and shorted to the cathode; and
an organic masking layer that is formed within openings of the metal mesh.

14. The display defined in claim 1, further comprising:
one or more conductive cutting structures that are interposed between adjacent pixels in the plurality of pixels, wherein the one or more conductive cutting structures have undercuts that create discontinuities in the organic light-emitting diode layers and the cathode and wherein the cathode is shorted to the one or more conductive cutting structures.

15. The display defined in claim 1, further comprising:
a pixel definition layer that defines apertures for the plurality of pixels, wherein the pixel definition layer has an optical density between 0.5 μm⁻¹ and 1.0 μm⁻¹.

16. A display comprising a plurality of pixels, wherein each pixel in the plurality of pixels comprises:
an anode;
a cathode comprising a transparent conductive oxide layer; and
organic light-emitting diode layers that are interposed between the anode and the cathode, wherein the organic light-emitting diode layers comprise:
an emissive layer;
an electron injection layer that is interposed between the emissive layer and the cathode, wherein the electron injection layer comprises a first material having a first work function that is less than 5 eV; and
an electron transport layer that is interposed between the emissive layer and the electron injection layer, wherein the electron transport layer comprises a bulk material and a dopant and wherein the dopant comprises a second material having a second work function that is less than 5 eV.

17. The display defined in claim 16, wherein the second material is the same as the first material.

18. The display defined in claim 16, wherein each one of the first and second materials comprises a material selected from the group consisting of: lithium, sodium, potassium, cesium, magnesium, calcium, barium, and ytterbium.

19. The display defined in claim 16, wherein the dopant comprises between 0.01% and 10% of the electron transport layer by weight.

20. The display defined in claim 16, wherein the organic light-emitting diode layers for each pixel in the plurality of pixels further comprise:
an additional electron transport layer that is interposed between the emissive layer and the electron transport layer.

21. A display comprising a plurality of pixels, wherein each pixel in the plurality of pixels comprises:
an anode;
organic light-emitting diode layers that overlap the anode, wherein the organic light-emitting diode layers comprise:
an emissive layer;
a hole transport layer interposed between the emissive layer and the anode;
a hole injection layer interposed between the hole transport layer and the anode;
an electron transport layer, wherein the emissive layer is interposed between the electron transport layer and the hole transport layer; and
an electron injection layer, wherein the electron transport layer is interposed between the electron injection layer and the emissive layer and wherein the electron injection layer serves as a cathode for the pixel; and
one or more dielectric layers that overlap the organic light-emitting diode layers, wherein the one or more dielectric layers are in direct contact with an upper surface of the electron injection layer.
